(19) United States
(12) Patent Application Publication
(10) Pub. No.: US 2024/0282661 A1
(43) Pub. Date: Aug. 22, 2024

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Chih-Chien Pan, Taipei City (TW); Yu-Wei Lin, New Taipei City (TW); Pu Wang, Hsinchu City (TW); Li-Hui Cheng, New Taipei City (TW)

(73) Assignee: Taiwan Semiconductor Manufacturing Company, Ltd., Hsinchu (TW)

(21) Appl. No.: 18/173,033

(22) Filed: Feb. 22, 2023

(51) Int. Cl. H01L 23/373; H01L 23/00; H01L 23/31; H01L 23/498; H01L 25/07; H01L 29/68

(52) U.S. Cl. CPC H01L 23/373; H01L 23/3128; H01L 23/49816; H01L 23/49827; H01L 24/16; H01L 24/97; H01L 25/072; H01L 29/685; H01L 2224/32225; H01L 2224/97; H01L 2924/1434

(57) ABSTRACT

A semiconductor package and a manufacturing method thereof are provided. The package includes a substrate, and first, second and third semiconductor elements disposed on and electrically connected to the substrate. A heat transfer enhancing layer, a thermal conductive material layer and an adhesive material layer are respectively disposed on and joined to the first, second and third semiconductor elements. A lid is disposed over the first, second and third semiconductor elements, and joined to the heat transfer enhancing layer, the thermal conductive material layer and the adhesive material layer. The thermal conductive material layer has a thermal conductivity lower than that of the heat transfer enhancing layer and higher than that of the adhesive material layer, and the thermal conductive material layer has a bonding strength larger than that of the heat transfer enhancing layer and smaller than that of the adhesive material layer.

### BACKGROUND

In the field of semiconductor packaging, it is important to meet the need for efficient heat dissipation while satisfying the demand for miniaturization and integration of multiple semiconductor components, subunits and electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 9 are schematic cross-sectional views illustrating structures produced during various stages of a manufacturing process of a semiconductor package in accordance with some embodiments of the disclosure.

FIG. 10A and FIG. 10B are schematic top views illustrating a semiconductor package in accordance with some embodiments of the disclosure.

FIG. 11 is a schematic cross-sectional view illustrating a semiconductor package in accordance with some embodiments of the disclosure.

FIG. 12 to FIG. 16 are schematic views illustrating portions of structures produced during a manufacturing process of a semiconductor package in accordance with some embodiments of the disclosure.

FIG. 17 is a schematic top view of a lid in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

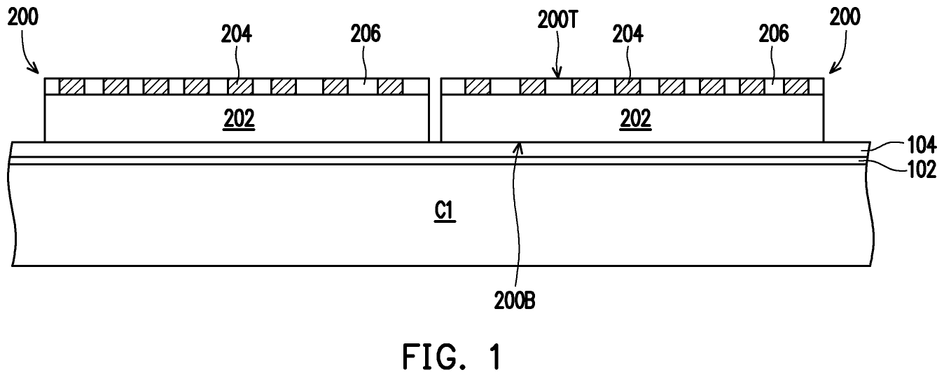

FIG. 1 to FIG. 9 are schematic cross-sectional views illustrating structures produced during a manufacturing process of a semiconductor package in accordance with some embodiments of the disclosure.

Referring to FIG. 1, in some embodiments, a carrier C1 is provided. In some embodiments, the carrier C1 is a glass substrate, a metal plate, a plastic supporting board or the like, but other suitable substrate materials may be used as long as the materials are able to withstand the subsequent steps of the process. In some embodiments, a de-bonding layer 102 may be formed over the carrier C1. In some embodiments, the de-bonding layer 102 includes a light-to-heat conversion (LTHC) release layer, which facilitates peeling the carrier C1 away from the semiconductor device in later manufacturing process(es). In some embodiments, the de-bonding layer 102 further includes an optional polymeric buffer layer or a glue layer. Later, a die attach film layer 104 is formed over the de-bonding layer 102.

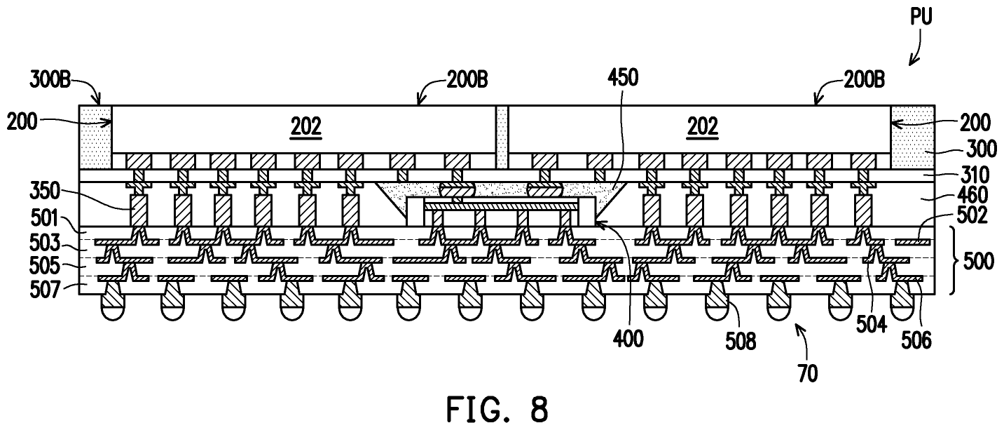

Referring to FIG. 1, in some embodiments, semiconductor structures 200 are provided and placed side-by-side on the carrier C1. In some embodiments, the semiconductor structures 200 are placed onto the carrier C1 through a pick-and-place method. Even though only two semiconductor structures 200 are presented in FIG. 1 for illustrative purposes, a plurality of semiconductor structures 200 may be provided on the carrier C1 to produce multiple package units PU (see FIG. 8) using wafer-level packaging technology. Furthermore, the number of the semiconductor structures 200 included in each package unit PU is not limited by the figures, and may be chosen based on product requirement. In some alternative embodiments, a package unit PU may include one or more than two semiconductor structures 200. In some embodiments, one individual semiconductor structure 200 includes a semiconductor portion 202, contact pads 204, and a passivation layer 206. In some embodiments, the contact pads 204 are formed on the semiconductor portion 202 and embedded in the passivation layer 206, while the passivation layer 206 exposes contact pads 204. In some alternative embodiments, the contact pads 204 may be covered by the passivation layer 206 temporarily, and later are exposed for electrical connection.

In some embodiments, the semiconductor structures 200 are placed on the die attach film layer 104 with the top surfaces 200T of the semiconductor structures 200 facing away from the carrier C1, while backside surfaces 200B of the semiconductor structures 200 face and contact the die attach film layer 104. The die attach film layer 104 that is in contact with the backside surfaces 200B of the semiconductor structures 200 secures the semiconductor structures 200. In some embodiments, the die attach film layer 104 includes a pressure adhesive, a thermally curable adhesive, or the like.

In some embodiments, the semiconductor portion 202 may be made of semiconductor materials, such as silicon, germanium, compound semiconductor materials of the groups III-V of the periodic table. In some embodiments, the semiconductor portion 202 includes active devices (e.g., transistors, diodes or the like) and optionally passive devices (e.g., resistors, capacitors, inductors, or the like) formed therein. In certain embodiments, the contact pads 204 include aluminum pads, copper pads, or other suitable metal pads. In some embodiments, the passivation layer 206 may be a single layer or a multi-layered structure, including a silicon oxide layer, a silicon nitride layer, a silicon oxynitride layer, a dielectric layer formed by other suitable dielectric materials, or combinations thereof. In some embodiments, the top surface 200T of the semiconductor structure 200 having the contact pads 204 exposed therefrom may be regarded as the active surface of the semiconductor structure 200.

In some embodiments, the semiconductor structure(s) 200 includes or is a package subunit including a multi-chip stacked package, an integrated fan-out (InFO) package, a three-dimensional integrated circuit (3DIC) package, or a combination thereof. In some embodiments, the semiconductor structure(s) 200 includes an InFO package subunit. In some embodiments, the semiconductor structure(s) 200 includes a semiconductor die having active elements and/or passive elements. In some embodiments, the semiconductor structure(s) 200 includes one or more semiconductor dies performing different functions, and the semiconductor dies may independently be or include a logic die, such as a central processing unit (CPU) die, a graphic processing unit (GPU) die, a micro control unit (MCU) die, an input-output (I/O) die, a baseband (BB) die, a system-on-chip (SoC) die, a large-scale integrated circuit (LSI) die, an application-specific IC (ASIC) die, or an application processor (AP) die, or may independently be or include a memory die such as a high bandwidth memory (HBM) die. In some embodiments, the semiconductor structure(s) 200 includes at least one of AP dies, LSI dies or SoC dies. The type(s) of the dies included in the semiconductor structures 200 within a package unit PU may be the same or different depending on product designs. In one embodiment, at least two types of semiconductor structures 200 are included within a package unit PU, one type of the semiconductor structures 200 includes at least one ASIC die, and the other type of the semiconductor structures 200 includes at least one HBM die.

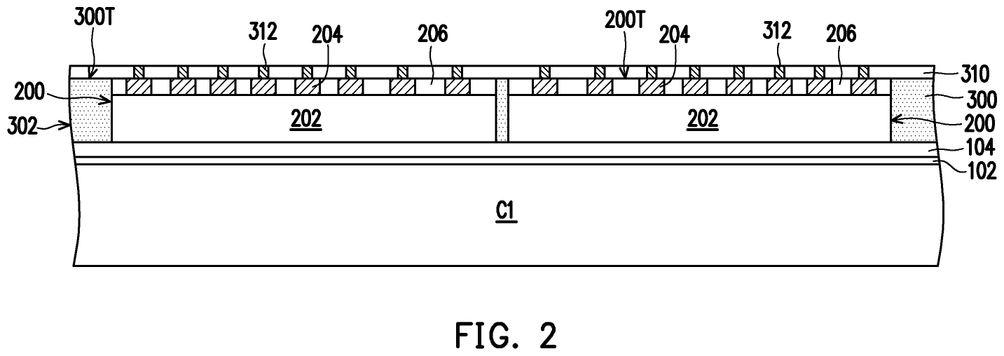

Referring to FIG. 2, an encapsulant 300 is formed over the die attach film layer 104 on the carrier C1 to encapsulate the semiconductor structures 200. In some embodiments, the encapsulant 300 includes a molding compound or a polymeric material, such as epoxy resin, acrylic resin, phenolic resin or the like, or other suitable insulating materials. In some embodiments, the encapsulant 300 optionally includes silica fillers or ceramic fillers. In some embodiments, the encapsulant 300 may be originally formed by a molding process (such as compression molding, transfer molding or over-molding process) or a spin-coating process to completely cover the semiconductor structures 200. In some embodiments, the encapsulant 300 is formed by over-molding and later planarization. In some embodiments, the planarization of the encapsulant 300 includes performing a mechanical grinding process and/or a chemical mechanical polishing (CMP) process. In some embodiments, the planarization process is performed until the contact pads 204 of the semiconductor structures 200 are exposed. In some embodiments, portions of the passivation layer 206 may be removed during the planarization process of the encapsulant 300. In some embodiments, following the planarization process, the contact pads 204 are exposed from the top surfaces 200T of the semiconductor structures 200, and the top surfaces 200T and the top surface 300T of the encapsulant 300 may be substantially coplanar and leveled (at a same level height).

As illustrated in FIG. 2, the encapsulant 300 laterally encapsulates the semiconductor structures 200. With the formation of the encapsulant 300, a reconstructed wafer 302 is obtained. In some embodiments, the reconstructed wafer 302 includes a plurality of package units PU (see FIG. 8), and the following processes are performed to the reconstructed wafer 302 (at a wafer level) to process the multiple package units PU. In the figures, a portion of reconstructed wafer structure including a single package unit PU is shown for simplicity, and the disclosure is not limited by the number of package units being shown or produced.

In some embodiments, a protective dielectric layer 310 and conductive posts 312 are formed on the reconstructed wafer 302. In some embodiments, the protective dielectric layer 310 is formed globally over the reconstructed wafer 302 covering the encapsulant 300 and the semiconductor structures 200. Later, the conductive posts 312 are formed inside the openings of the protective dielectric layer 310. In some embodiments, the conductive posts 312 are electrically connected to the contact pads 204 and the protective dielectric layer 310 surrounds the conductive posts 312. In certain embodiments, the conductive posts 312 include copper, copper alloys, aluminum, or other suitable metallic material. Throughout the description, the term “copper” is intended to include substantially pure elemental copper, copper containing unavoidable impurities, and copper alloys containing elements such as tantalum, indium, tin, zinc, manganese, chromium, titanium, germanium, strontium, platinum, magnesium, aluminum, or zirconium.

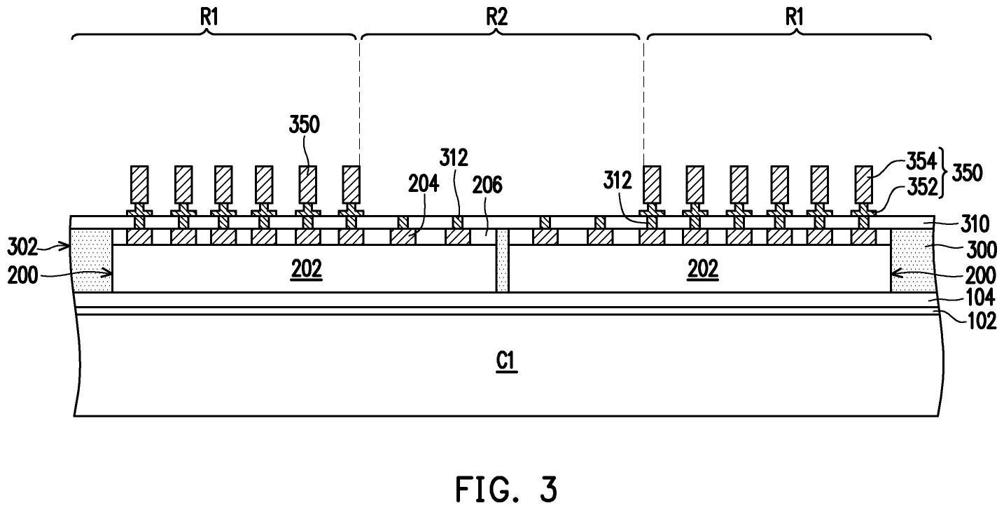

Referring to FIG. 3, a plurality of through insulator vias (TIVs) 350 is formed on the conductive posts 312. In some embodiments, the TIVs 350 are formed in the non-die-placement region R1 instead of the die-placement region R2. For example, the TIVs 350 are preformed and attached to the conductive posts 312 in the non-die-placement region R1, surrounding the die-placement region R2. In some embodiments, the TIVs 350 includes metallic stubs 352 and metallic pillars 354 connected to the stubs 352. In order to establish electrical connection, the TIVs 350 are connected to the conductive posts 312 and further connected to the conductive pads 204 of the semiconductor structures 200. For example, pre-fabricated TIVs 350 (e.g., pre-fabricated copper pillars) may be picked-and-placed and bonded to the conductive posts 312. In some embodiments, the TIVs 350 are formed directly on the protective dielectric layer 310 and conductive posts 312 though plating with a mask pattern (not shown). In some embodiments, the formation of the TIVs 350 involves forming a seed material layer (such as titanium/copper composite layer), forming the mask pattern with openings, forming copper pillars through a plating process, and removing the mask pattern. The locations for the formed TIVs 350 mainly correspond to the locations of the conductive vias 312 in the non-die-placement region R1.

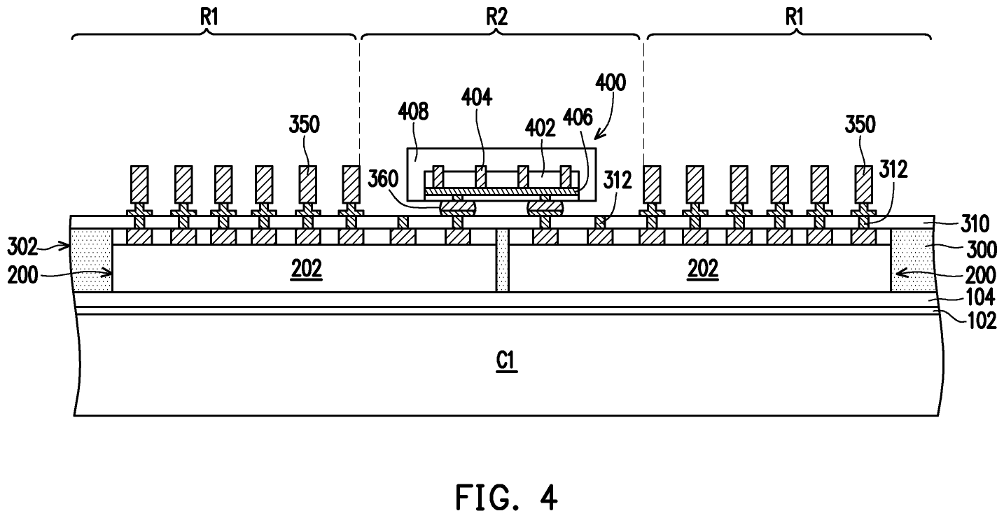

In some embodiments, referring to FIG. 4, semiconductor dies 400 are mounted onto and bonded to the conductive posts 312 inlaid in the protective dielectric layer 310. Even though only one semiconductor die 400 is presented in FIG. 4 for illustrative purposes, it is understood that a plurality of semiconductor dies 400 are provided for the whole reconstructed wafer 302. In some embodiments, the semiconductor die 400 is bonded with and electrically connected with the conductive posts 312 in the die-placement region R2 through the connectors 360 located between the conductive posts 312 and semiconductor die 400. In some embodiments, a plurality of semiconductor dies 400 may be provided in each package unit PU. In some embodiments, the semiconductor die 400 includes a semiconductor body 402, through semiconductor vias (TSVs) 404, an interconnection layer 406 and a covering layer 408. The TSVs 404 extend from the interconnection layer 406 through the semiconductor body 402, protrude from the semiconductor body 402 and are covered by the covering layer 408.

In some embodiments, the semiconductor body 402 includes semiconductor materials, such as silicon, germanium, silicon germanium, silicon carbide, or compound semiconductor materials of the groups III-V of the periodic table. In some embodiments, the semiconductor body 402 includes active devices and optionally passive device formed therein. In some embodiments, the TSVs 404 include copper pillars, or copper alloy columns. In some embodiments, the interconnection layer 406 includes metallic routing lines and vias for establishing electrical interconnection among the devices/components inside the semiconductor die 400. In some embodiments, the covering layer 408 includes a polymeric material, an encapsulant material or a molding compound with a suitable insulating material. In some embodiments, the connectors 360 includes micro-bumps, copper bumps or metallic posts. In some embodiments, referring to FIG. 4, the semiconductor die 400 is electrically connected with the underlying semiconductor structures 200 through the connectors 360 and the conductive posts 312.

In some embodiments, the semiconductor die 400 is or includes one or more logic dies, such as a central processing unit (CPU) die, a graphic processing unit (GPU) die, a micro control unit (MCU) die, an input-output (I/O) die, a baseband (BB) die, a field-programmable gate array (FPGA) die, an application-specific IC (ASIC) die, an application processor (AP) die, or the like. The type(s) of the dies included within a package unit PU may be the same or different depending on product designs. In one embodiment, the semiconductor structures 200 are electrically connected and communicated by the semiconductor die 400, and the semiconductor die 400 functions as an interconnection bridge or a local interconnection structure for the semiconductor structures 200 below.

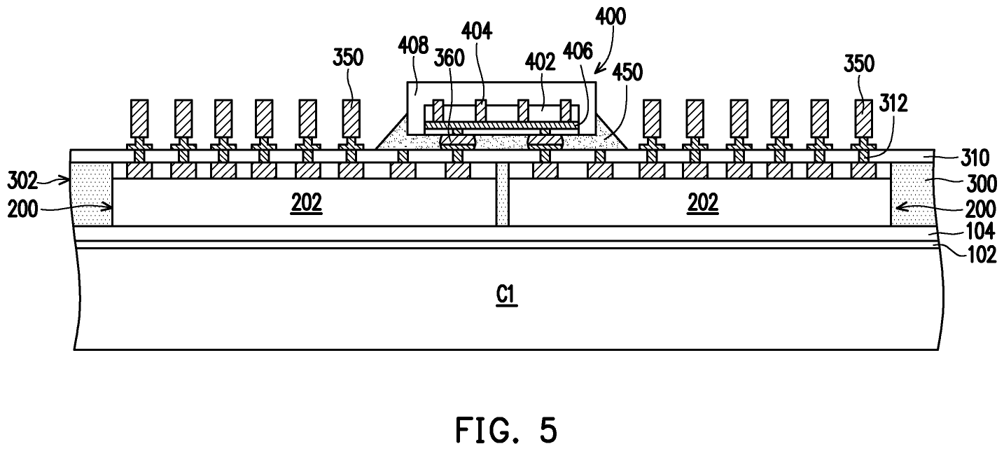

Referring to FIG. 5, in some embodiments, after bonding the semiconductor die 400 with the semiconductor structures 200, an underfill 450 is formed between the semiconductor die 400 and the protective dielectric layer 310. In some embodiments, the underfill 450 fills the gap between the semiconductor die 400 and the protective dielectric layer 310, surrounds the connectors 360 and covers the conductive posts 312. For example, the underfill 450 may be filled into the space between the connectors 360 and the protective dielectric layer 310 by a capillary flow process and then cured. In some embodiments, the underfill 450 includes a resin material including an epoxy resin material. In some embodiments, the underfill 450 filled between the semiconductor die 400 and the protective dielectric layer 310 strengthens the bonding and structural integrity.

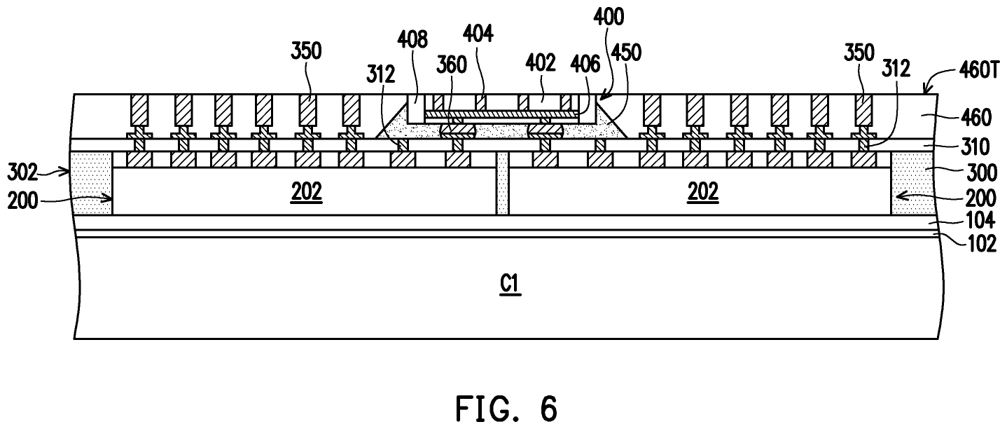

In some embodiments, referring to FIG. 6, a molding compound 460 is formed globally over the reconstructed wafer 302 and on the protective dielectric layer 310 to cover the TIVs 350, the semiconductor die 400 and the underfill 450. In some embodiments, the molding compound 460 is formed by over-molding and a planarization process is performed to remove the extra materials to expose the TIVs 350 and the TSVs 404. In some embodiments, the planarization process includes performing a mechanical grinding process and/or a CMP process. In some embodiments, the planarization process is performed until the TSVs 404 of the semiconductor die 400 are exposed and the tops of the TIVs 350 are exposed from the molding compound 460. In some embodiments, portions of the molding compound 460 are removed to expose the TIVs 350 and portions of the covering layer 408 are removed to expose the TSVs 404 through the planarization process. In some embodiments, following the planarization process, the tops of the TSVs 404, the tops of the TIVs 350 are substantially coplanar and leveled (at a same level height) with the top surface of the covering layer 408 and the top surface 460T of the molding compound 460.

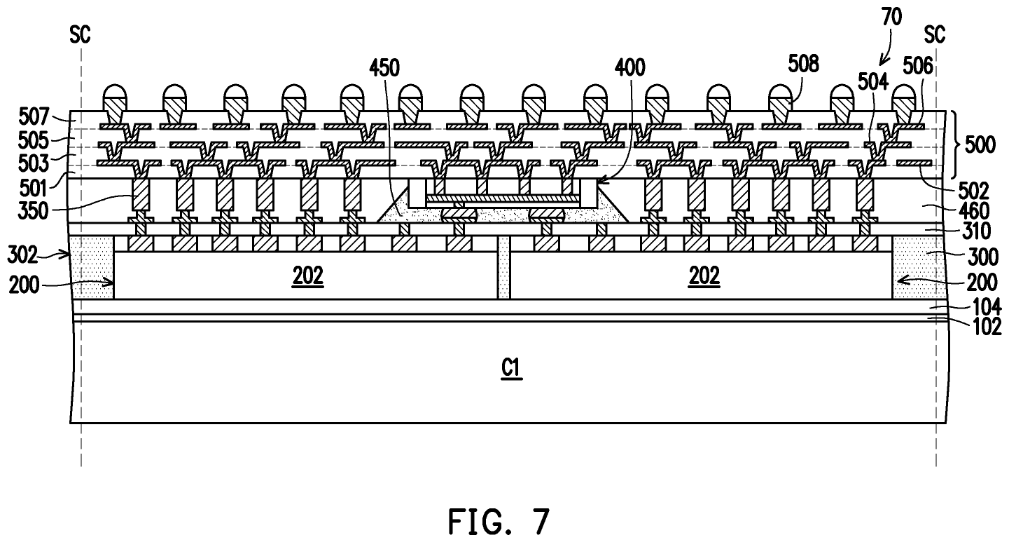

Referring to FIG. 7, in some embodiments, a redistribution structure 500 is formed globally over the reconstructed wafer 302 and is formed on the molding compound 460 at the backside of the semiconductor die(s) 400 to form the assembled structure 70. The redistribution structure 500 is formed over the die-placement region(s) R1 and the non-die-placement region(s) R2. In some embodiments, the redistribution structure 500 includes dielectric layers 501, 503, 505 and 507 stacked in alternation with metallization layers 502, 504 and 506, and conductive bumps 508. In some embodiments, the dielectric layers 501, 503, 505 and 507 and the metallization layers 502, 504 and 506 are sequentially formed over the molding compound 460, the TIVs 350 and the semiconductor die 400. The metallization layers 502, 504 and 506 are respectively sandwiched between the dielectric layers 501, 503, 505 and 507. In some embodiments, the metallization layers 502, 504, 506 each includes routing conductive traces and vias. In some embodiments, the bottommost metallization layer 502 is physically connected with the TIVs 350 and the exposed TSVs 404. In some embodiments, the conductive bumps 508 are located within the openings of the topmost dielectric layer 507 and located directly on the topmost metallization layer 506.

In some embodiments, a material of the metallization layers 502, 504, 506 includes copper, aluminum, or the like. In some embodiments, the material of the metallization layers 502, 504, 506 includes copper. The metallization layers 502, 504, 506 may be formed by, for example, electroplating, deposition, and/or photolithography and etching. In some embodiments, a material of the dielectric layers 501, 503, 505 and 507 independently includes polyimide (PI), benzocyclobutene (BCB), polybenzooxazole (PBO), combinations thereof, a photosensitive polymer material or any other suitable polymer-based dielectric material. The dielectric layers 501, 503, 505 and 507, for example, may be formed by suitable fabrication techniques such as coating, lamination, chemical vapor deposition (CVD), or the like. In some embodiments, more or less layers of dielectric layers or metallization layers may be formed in the redistribution structure 500 depending on production requirements. In some embodiments, the conductive bumps 508 include micro bumps, copper bumps, controlled collapse chip connection (C4) bumps, electroless nickel-electroless palladium-immersion gold technique (ENEPIG) formed bumps, or combinations thereof. In some embodiments, the conductive bumps 508 include under ball metallurgy (UBM) patterns and solder bumps formed thereon.

In some embodiments, referring to FIG. 7 and FIG. 8, a singulation process is performed to the assembled structure 70 to separate the package units so that individual semiconductor packages PU are obtained. In some embodiments, the singulation process typically involves performing a wafer dicing process with a rotating blade and/or a laser beam. For example, the singulation process includes performing a blade dicing process cutting through the assembled structure 70 (i.e. cutting through the redistribution structure 500, the molding compound 460, the protective dielectric layer 310 and the encapsulant 300 of the reconstructed wafer 302) along the scribe lanes SC arranged between individual package units PU. In some embodiments, the carrier Cl is separated from the semiconductor packages PU following singulation, and then removed. For example, the de-bonding layer 102 may be irradiated with a UV laser so that the carrier Cl and the de-bonding layer 102 are easily separated and peeled off from the semiconductor packages PU. In some embodiments, the die attach film 104 is also removed to expose the back surfaces 200B of the semiconductor structures 200 and the encapsulant 300. Nevertheless, the de-bonding process is not limited thereto, and other suitable de-bonding methods may be used in some alternative embodiments. Following singulation, referring to FIG. 8, the semiconductor packages PU is turned upside down, so that the top surface of the package PU includes the leveled back surfaces 200B of the semiconductor structures 200 and the surface 300B of the encapsulant 300.

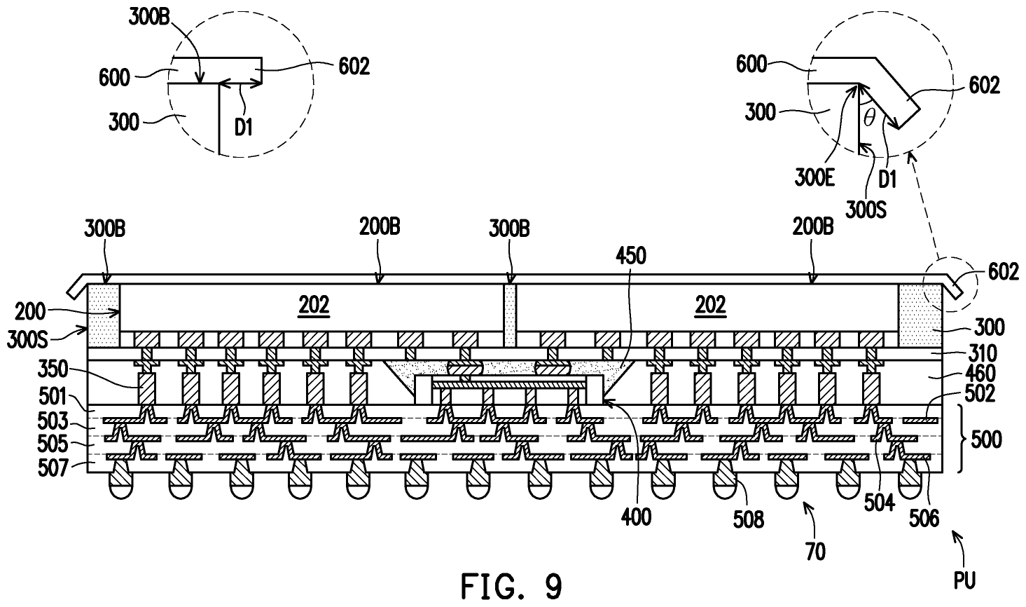

Referring to FIG. 9, a heat transfer enhancing layer 600 is formed on the top surface of the package PU, covering the back surfaces 200B of the semiconductor structures 200 and the surface 300B of the encapsulant 300. In some embodiments, the heat transfer enhancing layer 600 is preformed as a film with a suitable thickness and laminated directly on the top surface of the package PU. In some embodiments, the heat transfer enhancing layer 600 at least fully covers the back surfaces 200B of the semiconductor structures 200 and the surface 300B of the encapsulant 300 (i.e. the top surface of the package PU).

In some embodiments, the heat transfer enhancing layer 600 fully covers the top surface of the package PU and has extended portions 602 extending beyond the edges 300E of the encapsulant 300. In some embodiments, as seen in the enlarged partial view at the upper right part of FIG. 9, the extended portion 602 extends from the edge 300E of the encapsulant 300 outwardly with an extending length D1 (measuring from the edge 300E to the end of the extended portion 602). In some embodiments, the extended portion 602 extending beyond the edge 300E is overhung and spaced apart from the sidewall 300S of the encapsulant 300. In one embodiment, if the extending length D1 is long, the extended portion 602 is at an angle with the sidewalls 300S of the encapsulant 300. In some embodiments, the angle θ between the slant extended portion 602 and the sidewall 300S of the encapsulant 300 ranges from about 30 degrees to about 89 degrees, and the extending length D1 is about 5% to about 15% of the length or the width of the package PU. In some embodiments, as seen in the enlarged partial view at the upper left part of FIG. 9, the extended portion 602 may be substantially parallel to the surface 300B of the encapsulant if the extending length D1 is small (smaller than 5% of the length or the width of the package PU). In some embodiments, the heat transfer enhancing layer 600 is made of or includes a film type thermal interface material (TIM) and has a stiffness large enough to hold its shape when overhung.

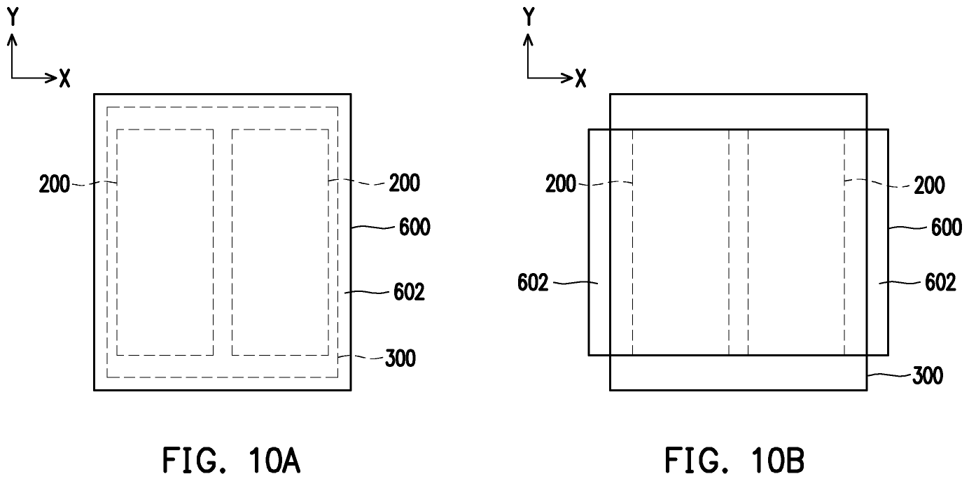

FIG. 10A and FIG. 10B are schematic top views illustrating a semiconductor package in accordance with some embodiments of the disclosure. The dashed lines indicate the span (distribution area) of the semiconductor structure(s) 200 and the encapsulant 300 of the package PU, and may be considered as vertical projections of the respective elements in the plane defined by the protective dielectric layer 310. From the schematic top view shown in FIG. 10A, it is seen that the span of the heat transfer enhancing layer 600 is larger than the span of the encapsulant 300 of the package PU (i.e. the span of the package PU) in X-direction and Y-direction, and the span of the encapsulant 300 is smaller than and fully overlaps with (i.e. falls within) the span of the heat transfer enhancing layer 600. In some embodiments, the extended portion 602 is ring-shaped and surrounds the periphery of the encapsulant 300. In some embodiments, the extending length of the extended portion 602 is substantially the same through the entire ring-shaped extended portion 602. In some embodiments, the extending length of the extended portion 602 varies for the whole ring-shaped extended portion 602.

From the schematic top view shown in FIG. 10B, it is seen that the span of the heat transfer enhancing layer 600 partially overlaps with the span of the encapsulant 300 of the package. That is, the width of the heat transfer enhancing layer 600 in the X-direction is larger than that of the encapsulant 300 (i.e. width of the package PU), while the length of the heat transfer enhancing layer 600 in the Y-direction is smaller than that of the encapsulant 300 of the package PU (i.e. length of the package PU). As seen in FIG. 10B, the extended portions 602 are located by the two opposite Y-extending sides (extending in the Y-direction) of the encapsulant 300. In some embodiments, the extended portions 602 at two sides have substantially the same extending length. In some embodiments, the extended portions 602 at two sides have different extending lengths.

In alternative embodiments, the span of the heat transfer enhancing layer 600 is smaller than and fully overlaps with the span of the package unit PU. That is, the edges of the heat transfer enhancing layer 600 are recessed from the edges of the package unit PU, and the edges of the package unit PU (or top edges of the encapsulant 300) are exposed from the heat transfer enhancing layer 600.

In some embodiments, the material of the heat transfer enhancing layer 600 includes an adhesive material with higher thermal conductivity. For example, the heat transfer enhancing layer 600 has a thermal conductivity ranging from about 10 (W/cm*k) to about 30 (W/cm*k). In some embodiments, the heat transfer enhancing layer 600 is made of a film type thermal interface material (TIM). For example, the film-type TIM has solid texture with a stiffness ranging from about 950-1150 newton per millimeter (N/mm). For example, the film-type TIM has a stiffness of about 1050 N/mm. In some embodiments, the heat transfer enhancing layer 600 made of the film-type TIM may be rigid, and are attached through picking and placing. Alternatively, the heat transfer enhancing layer 600 is transferred by die-coating or rolling to the intended location and then laminated onto the package. For example, the film-type TIM may have a tackiness ranging from about 4-6 N*mm. For example, the film-type TIM has a tackiness of about 5 N*mm. In some embodiments, the film type TIM includes a polymeric adhesive material such as silicone or epoxy resins and thermally conductive fillers such as metallic fillers of silver (Ag), Cu, tin (Sn), indium (In), or combinations thereof. In some embodiments, the film type TIM includes carbon nanotube (CNT), graphite, or graphene. In some embodiments, the film type TIM includes silicone or silicone-based polymer material and metallic fillers. In some embodiments, the heat transfer enhancing layer 600 that is formed from a film type TIM with the ability to conform to surfaces of varying roughness can achieve film coverage rate of about 90% to about 99%.

In some embodiments, as the heat transfer enhancing layer 600 is formed from a film type TIM, the applicability and rework ability of the heat transfer enhancing layer 600 are greatly improved. Further, the high thermal conductivity of the heat transfer enhancing layer 600 leads to excellent heat transfer performance and results in up to 30% improvement in the thermal dissipation performance of the package.

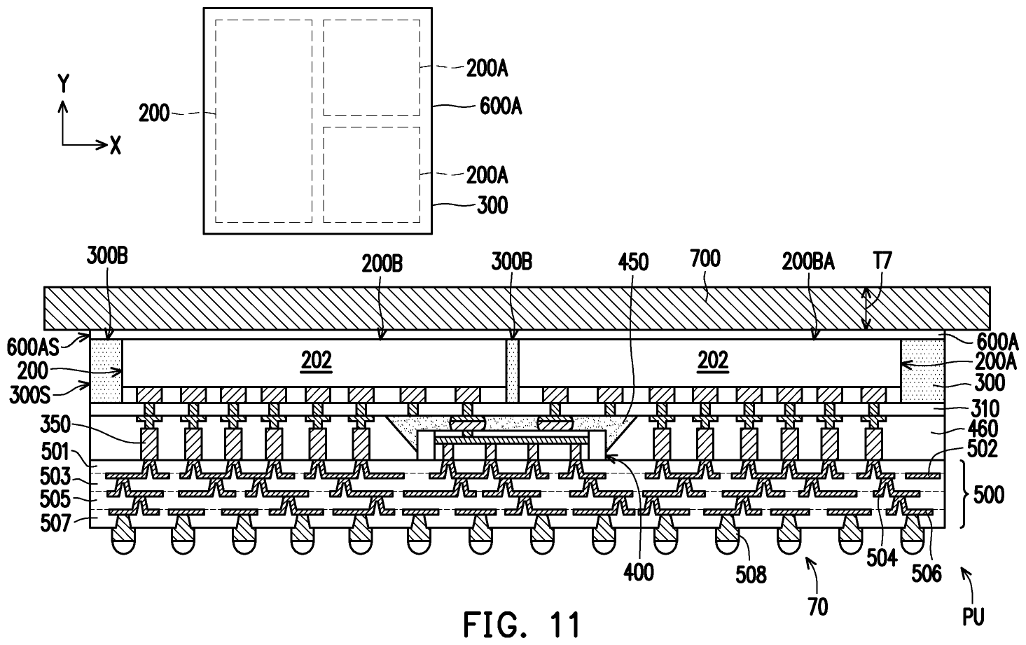

FIG. 11 is a schematic cross-sectional view illustrating a semiconductor package in accordance with some embodiments of the disclosure. The structure shown in FIG. 11 is similar to the structure of FIG. 9, and similar or the same parts or elements are labeled with the same reference labels. Referring to FIG. 11, in some embodiments, the heat transfer enhancing layer 600A fully covers the back surface 200B of the semiconductor structures 200, the back surfaces 200BA of the semiconductor structures 200A, and the surface 300B of the encapsulant 300 (i.e. the top surface of the package PU). In some embodiments, the semiconductor structures 200 and 200A may be different types of packages or include different types of dies of various functions. In some embodiments, the semiconductor structure 200 has dimensions larger than those of the semiconductor structures 200A. In some embodiments, as the semiconductor structures 200 and 200A have substantially the same height (thickness) and the back surfaces 200B and 200BA are coplanar and leveled, the heat transfer enhancing layer 600A that is made of a film type thermal interface material (TIM) fully covers the back surfaces 200B and 200BA with a good coverage rate. From the schematic top view shown in the upper part of FIG. 11, it is seen that the span of the heat transfer enhancing layer 600A is substantially the same as the span of the encapsulant 300 of the package PU (i.e. the span of the package PU) in X-direction and Y-direction, and the span of the encapsulant 300 fully overlaps with the span of the heat transfer enhancing layer 600A. From the schematic cross-sectional view of FIG. 11, the heat transfer enhancing layer 600A directly contacts the back surface 200B of the semiconductor structures 200, the back surfaces 200BA of the semiconductor structures 200A, and the surface 300B of the encapsulant 300, and the sidewalls 600AS of the heat transfer enhancing layer 600A substantially vertically aligned with the sidewalls 300S of the encapsulant 300. In some embodiments, the heat transfer enhancing layer 600A is formed without extended portion.

In some embodiments, as seen in FIG. 11, a heat dissipation covering 700 is disposed on and fixed onto the heat transfer enhancing layer 600A for promoting heat dissipation. In some embodiments, the heat dissipation covering 700 is or includes a metal sheet or a metal lid made of copper or copper alloys. For example, the heat dissipation covering 700 has a uniform thickness T7 and is pre-formed by stamping, punching or molding. In some embodiments, the span of the heat dissipation covering 700 is larger than the span of the package unit PU.

In some embodiments, the semiconductor package PU may be a package element integrated into larger semiconductor packages or electronic products.

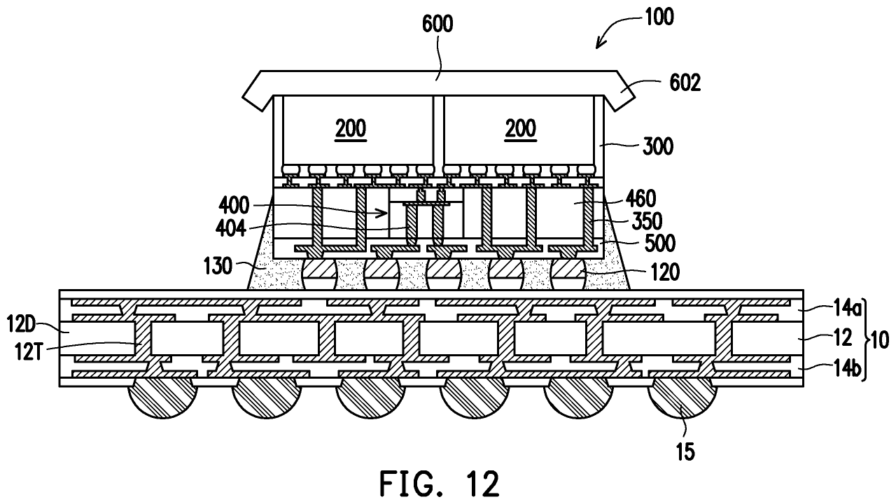

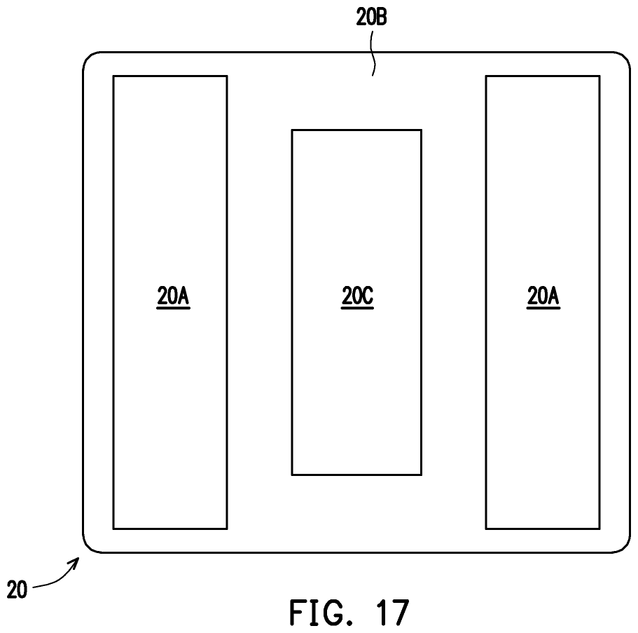

FIG. 12 to FIG. 16 are schematic views illustrating portions of structures produced during a manufacturing process of a semiconductor package in accordance with some embodiments of the disclosure. FIG. 17 is a schematic top view of a lid in accordance with some embodiments of the disclosure.

Referring to FIG. 12, a substrate 10 is provided. In some embodiments, the substrate 10 includes a circuit substrate, a multilayered board substrate or an organic substrate. In some embodiments, the substrate 10 is a multilayered circuit board substrate or a system board circuit substrate. In some embodiments, the substrate 10 includes a core layer 12, a first build-up layer 14a disposed on a top surface of the core layer 12 and a second build-up layer 14b disposed on a bottom surface of the core layer 12. In some embodiments, conductive balls 15 are formed on the bottom surface of the substrate 10. In some embodiments, the core layer 12 includes a core dielectric layer 12D and plated through holes 12T embedded in and penetrate through the core dielectric layer. In some embodiments, the core dielectric layer 12D includes prepreg, polyimide, glass fibers, photo image dielectric (PID), Ajinomoto buildup film (ABF), a combination thereof, or the like, and the through holes 12T are lined with a conductive material (such as copper) and filled up with an insulating material. In some embodiments, the formation of the first build-up layer 14a or the second build-up layer 14b involves film lamination of dielectric layers and followed by forming conductive patterns in alternation. It is understood that the total number of layers of the first build-up layer 14a and the second build-up layer 14b may be modified based on the product requirements. In some embodiments, the materials of the dielectric layers include polyimide, PBO, BCB, prepreg, Ajinomoto buildup film (ABF), a combination thereof, or the like. In some embodiments, the materials of the conductive patterns include a metal material, such as aluminum, titanium, copper, nickel, tungsten, alloys thereof and/or combinations thereof. In some embodiments, the conductive patterns are formed by deposition, or plating. In some embodiments, the conductive balls 15 include solder balls, and the solder material of the solder balls includes, for example, lead-based solders such as PbSn compositions, or lead-free solders including InSb compositions, SnCu compositions or SnAg compositions.

Referring to FIG. 12, a semiconductor package element 100 is mounted on the substrate 10 and bonded to the substrate 10 through a plurality of conductive bumps 120. The semiconductor package element 100 is similar to the structure of the package PU fabricated through the processes depicted in FIG. 1-9 and depicted in FIG. 10A-10B and FIG. 11. In some embodiments, the semiconductor package element 100 is mounted onto the substrate 10 and bonded to the substrate 10. In some embodiments, the semiconductor package element 100 is bonded to the substrate 10 via a soldering process, a reflow process, or other processes requiring heating conditions. In some embodiments, a reflow process is performed so that the semiconductor package element 100 is bonded to the bond pads or terminals (not shown) of the substrate 10 through the conductive bumps 120. In some embodiments, the conductive bumps 120 include micro bumps, C4 bumps, copper bumps, ENEPIG formed bumps, or a combination thereof. In some embodiments, the connectors 102 include C4 bumps or micro bumps. In some embodiments, the conductive bumps 120 include a metallic material such as copper, aluminum, gold, nickel, silver, palladium, tin, a solder material, or combinations thereof. In some embodiments, the conductive bumps 120 are formed by using electro plating, electroless plating, screen-printing or jet printing techniques.

In some embodiments, the semiconductor package element 100 includes or is a package including a multi-chip stacked package, a CoW package, an InFO package, a CoWoS package, a 3DIC package, or a combination thereof. In some embodiments, the semiconductor package element 100 includes an InFO package. In some embodiments, the semiconductor package element 100 includes the redistribution structure 500, at least a semiconductor die 400 with TSVs 404 and TSVs 350 laterally wrapped by the molding compound 460, the semiconductor structures 200 laterally wrapped by the encapsulant 300 and the heat transfer enhancing layer 600 with the extended portion(s) 602. In some embodiments, the semiconductor package element 100 includes more than one of AP dies, LSI dies or SoC dies.

In some embodiments, the semiconductor package element 100 is bonded to and electrically connected to the substrate 10 through the conductive bumps 120. In some embodiments, referring to FIG. 12, an underfill 130 is formed between the redistribution structure 500 of the semiconductor package element 100 and the substrate 10 surrounding the conductive bumps 120. In some embodiments, the underfill 130 covers the bottom surface of the semiconductor package element 100 and partially covers the sidewalls of the semiconductor package element 100.

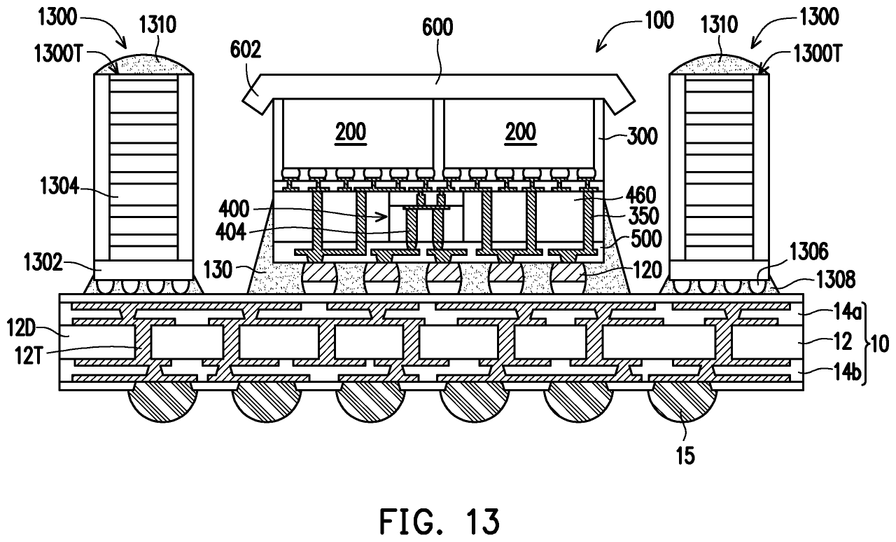

In some embodiments, referring to FIG. 13, semiconductor elements 1300 are provided and mounted onto the substrate 10, and the semiconductor elements 1300 are arranged beside the semiconductor package element 100 and spaced apart from the semiconductor package element 100 with a distance. In some embodiments, the semiconductor element(s) 1300 includes one or more memory dies, and the memory dies are HBM die including a plurality of stacked memory chips 1304 and a controller chip 1302, and the stacked memory chips 1304 and the controller chip 1302 are electrically connected. As seen in FIG. 13, the semiconductor elements 1300 are bonded to and electrically connected to the substrate 10 through connectors 1306 with an underfill 1308 filling between the semiconductor element 1300 and the substrate 10. It is understood that bond pads, bumps pads and/or contact terminals are included in the substrate 10 for receiving the conductive bumps 120 and the connectors 1306, even they are not depicted in the figure. In some embodiments, the semiconductor package element 100 and the semiconductor elements 1300 may have different dimensions and different heights. In some embodiments, the semiconductor package element 100 and the semiconductor elements 1300 may have different dimensions and substantially the same height.

As seen in FIG. 13, thermal interface material (TIM) layers 1310 are formed on the top surfaces 1300T of some semiconductor elements 1300. In some embodiments, the TIM layers 1310 fully cover the top surfaces 1300T. In some embodiments, the TIM layers 1310 are formed of liquid-type thermal interface materials or gel-type thermal interface materials (gel-type TIMs). In some embodiments, the liquid-type TIM is dispensed in a flowable form on to the intended location (with a mold) and then cured into the solid form. In some embodiments, the gel-type TIMs are semi-flowable and dispensed in a paste form over the intended span and then cured into the solid form. In general, the TIM layers 1310 are in contact with the top surfaces 1300T of the semiconductor elements 1300, but the TIM layers 1310 do not extend over and contact the sidewalls of the semiconductor elements 1300. In some embodiments, liquid-type thermal interface materials or gel-type TIMs include a polymeric base material with thermally conductive fillers. In some embodiments, the polymeric base material includes polyimide, silicone or epoxy resins, and the thermally conductive fillers includes alumina, silver (Ag), Cu, tin (Sn), indium (In), or even graphite or graphene. For example, liquid-type thermal interface materials or gel-type TIMs may have a thermal conductivity higher than about 1 W/cm*k, or have a thermal conductivity ranging from about 3W/cm*k to about 6 W/cm*k. Due to the different types of thermal interface materials are used, the heat transfer enhancing layer 600 or 600A has higher thermal conductivity than those of the TIM layers 1310. Also, in some embodiments, the heat transfer enhancing layer 600 or 600A has a stiffness higher (greater) than that of the TIM layers 1310.

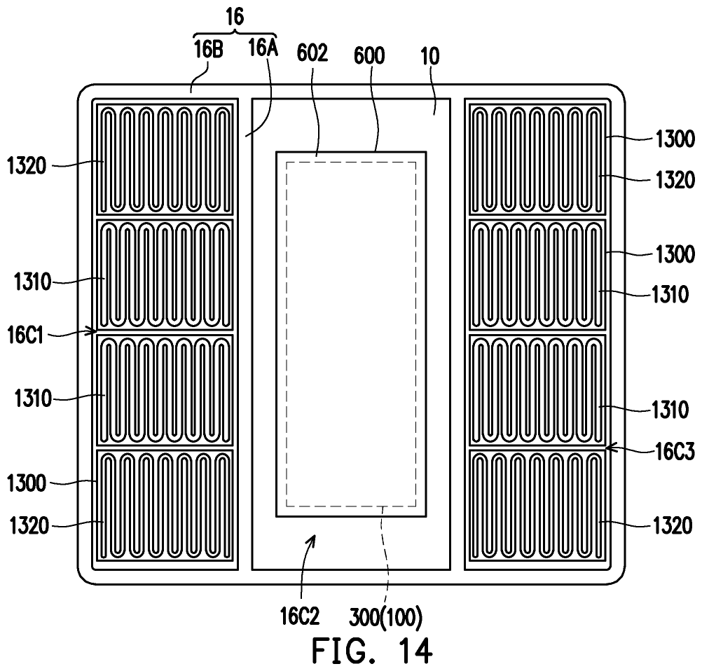

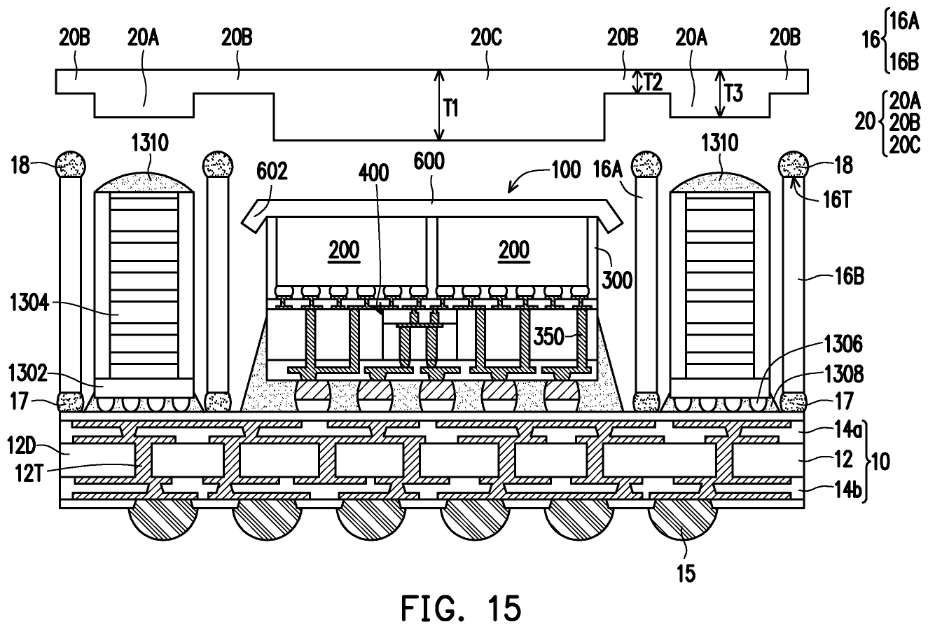

FIG. 14 is a schematic top view illustrating the relative arrangement of the semiconductor package element 100, semiconductor elements 1300 and wall structure 16. Referring to FIG. 13 and FIG. 14, a wall structure 16 is provided and mounted on the substrate 10. In some embodiments, for example, in FIG. 14, the wall structure 16 includes a ring wall 16B and ribs 16A dividing the enclosed space of the ring wall 16B into several compartments 16C1-16C3. The dashed line in FIG. 14 indicates the span of the semiconductor package element 100, and may be considered as a vertical projection of the semiconductor package element 100 onto the plane of the substrate 10. Referring to FIG. 14, after mounting and attaching the wall structure 16 onto the substrate 10, the wall structure 16 encircles a periphery of the package unit, the semiconductor elements 1300 are located within the left and right compartments 16C1 and 16C3, while the semiconductor package element 100 is located within the middle compartment 16C2. Not only the semiconductor package element 100 is spaced apart from the semiconductor elements 1300, but also the wall structure 16 is spaced apart form the semiconductor package element 100 and the semiconductor elements 1300. In some embodiments, the wall structure 16 is attached to the substrate through a first adhesive 17 (see FIG. 15). In some embodiments, the wall structure 16 is made of a highly thermally conductive material such as a metal or metallic material. In some embodiments, the wall structure 16 is made of a material with high rigidity and the wall structure 16 can reinforce the structural strength of the package unit.

In some embodiments, as seen in FIG. 14, the ring wall 16B of the wall structure 16 is a continuous ring-shaped loop wall and the ribs 16A are bar-shaped rib walls connected to the loop wall. In some alternative embodiments, instead of being a continuous structure, the wall structure 16 may include multiple bar-shaped walls and ribs arranged along, without enclosing, a periphery of the package unit.

In some embodiments, different types of elements and structures having different heat dissipation levels may be assembled in the same package. For example, compared with the semiconductor elements 1300, the semiconductor package element 100 may generate more heat per unit area, so that the heat transfer enhancing layer 600 having a higher thermal conductivity is disposed on the semiconductor package element 100 to satisfy the demanding thermal performance requirement. On the other hand, for the semiconductor elements 1300 that are less demanding for heat dissipation, the TIM layers 1310 or even adhesive material layers 1320 may be formed on the semiconductor elements to satisfy the moderate thermal performance requirement. Accordingly, for relatively higher heat-generating package components/parts, film-type TIMs of high thermal conductivity may be applied, and for relatively lower heat-generating package components/parts, gel-type TIMs may be applied. In accordance with some embodiments, the heat transfer enhancing layer 600 or 600A includes film-type TIMs of relatively high thermal conductivity, and the TIM layer(s) 1310 includes gel-type TIMs of a lower thermal conductivity. In accordance with some embodiments, the gel-type TIMs have a thermal conductivity ranging from about 3 W/cm*k to about 6 W/cm*k, while the film-type TIMs have a thermal conductivity ranging from about 10 W/cm*k to about 30 W/cm*k.

In accordance with some embodiments, as seen in FIG. 14, the semiconductor package element 100 includes the heat transfer enhancing layer 600 with the extended portion(s) 602. From the top view, it is seen that the extended portion 602 is in a ring-shape surrounding the span of the semiconductor package element 100. As seen in FIG. 14, in some embodiments, some semiconductor elements 1300 include the TIM layers 1310, and some semiconductor elements 1300 near the corners of the wall structure 16 include adhesive material layers 1320. As the wall structure 16 is located along the periphery of the package encircling the semiconductor elements 1300 and the package element 100, the semiconductor elements 1300 having the adhesive material layers 1320 formed therein are located near the corners of the package. By arranging the adhesive material layers 1320 near the corners of the package, better adhesion between the lid and the underlying elements is achieved and less delamination occurs.

In some embodiments, the adhesive material layers 1320 include adhesive materials, and the adhesive material layers 1320 have a bonding strength (or adhesion strength) larger than that of the TIM layers 1310 but have a thermal conductivity lower than that of the TIM layers 1310. In some embodiments, the adhesive material layer 1320 has a thermal conductivity lower than 1 W/cm*k or lower than 3 W/cm*k. In some embodiments, the adhesive material layer 1320 has a bonding strength larger than that of the TIM layer 1310, and the TIM layer 1310 has a bonding strength larger than that of the heat transfer enhancing layer 600. Depending on the layout of the product and the arrangement of the packaged components/elements, the application of the adhesive material layers 1320 on the semiconductor elements 300 near the corners of the package unit may help counterbalance the potential warpage of the package structure.

As seen in FIG. 14, before curing, the applied gel-type TIMs or the adhesive material may be paste-like, and the applied gel-type TIMs or the adhesive material may be dispensed as folded lines or loops over the intended area of the underlying elements. Alternatively, the gel-type TIMs or the adhesive material may be dispensed as discrete segments or blocks uniformly over the entire intended area of the underlying elements.

Referring to FIG. 15, a second adhesive 18 is applied on the top 16T surfaces of the ribs 16A and the ring wall 16B of the wall structure 16. In some embodiments, the material of the first adhesive 17 or second adhesive 18 is different from the material of the adhesive material layers 1320. Later, a lid 20 to be assembled to the wall structure 16 is provided. In some embodiments, the lid 20 is a metal lid such as an aluminum lid, a copper lid or a copper alloy lid, and is pre-formed by stamping, punching or molding. In some embodiments, the lid 20 includes a first portion 20C with a first thickness T1, a second portion 20B with a second thickness T2 and third portions 20A having a third thickness T3. In some embodiments, the lid 20 will be aligned before placing the lid 20 on the wall structure 16, for example, such that the first portion 20C corresponds to the semiconductor package element 100, the second portion 20B corresponds to the wall structure 16, and the third portions 20A correspond to the semiconductor elements 1300. In some embodiments, as seen from the schematic top view of FIG. 17, the first portion 20C is enclosed by the second portion 20B, and the third portions 20A that are located beside the first portion 20C are also encircled by the second portion 20B. In some embodiments, the second portion 20B connects and joins the first portion 20C and the third portions 20A. In some embodiments, the first thickness T1 is larger than the third thickness T3, and the third thickness T3 is larger than the second thickness T2. In some embodiments, the lid 20 may function as a heat spreader or heat dissipation lid for promoting heat dissipation for the underlying semiconductor elements. Further, the wall structure 16 joined with the lid 20 may be part of the heat dissipating structure

In alternative embodiments, when the semiconductor package element 100 and the semiconductor elements 1300 are provided with substantially the same height, the lid 20 of a substantially uniform thickness may be provided and attached to the wall structure 16 to cover the underlying structures and elements.

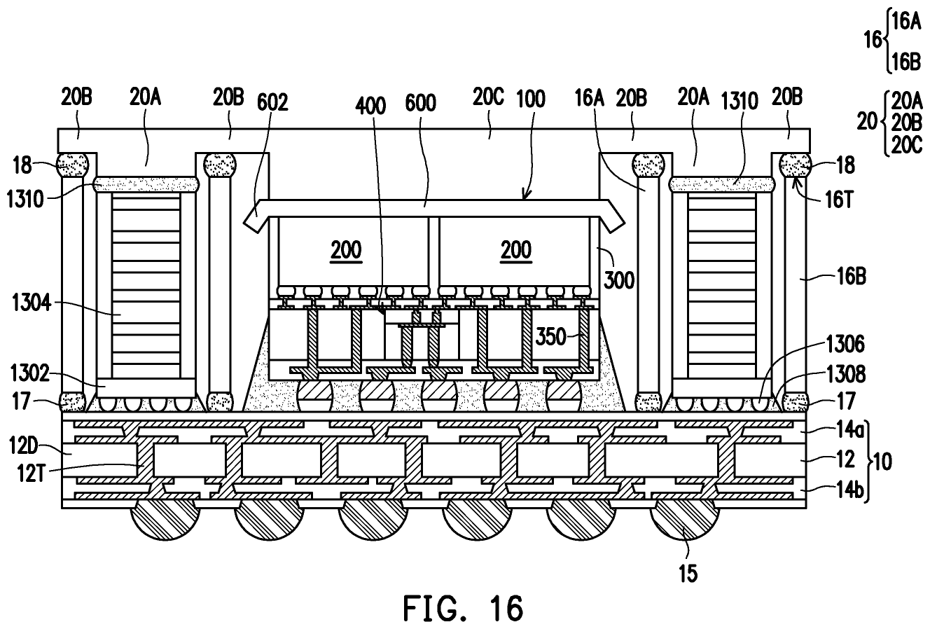

Referring to FIG. 16, the lid 20 is attached to the wall structure 16 through the second adhesive 18, attached to the semiconductor package element 100 through the heat transfer enhancing layer 600 and attached to the semiconductor elements 300 through the TIM layers 1310 and adhesive material layers 1320. In some embodiments, as the lid 20 is attached to the assembled structure, a reflow process may be performed to cure the adhesive material and the thermal interface materials. After the reflow process, the lid 20 is firmly attached to the assembled structure below. In some embodiments, the first portion 20C of the lid 20 attaches to and physically contacts the heat transfer enhancing layer 600 located on the semiconductor package element 100. In some embodiments, the third portions 20A of the lid 20 attaches to and physically contacts the TIM layers 1310 (as well as the adhesive material layers 1320) on the semiconductor elements 300. In some embodiments, the second portion 20B of the lid 20 fixes to the wall structure 16 below and physically contacts the second adhesive 18. In one embodiment, the lid 20 is firmly attached the wall structure 16, and the semiconductor package element 100 and the semiconductor elements 300 are sealed in respective compartments. After the curing, the cure TIM layers 1310 have a stiffness larger than that of the cured adhesive material layers 1320, but smaller than the stiffness of the heat transfer enhancing layer 600. As seen in FIG. 16, the heat transfer enhancing layer 600 located between the first portion 20C of the lid 20 and the semiconductor package element 100 has the extended portion(s) 602 overhung and protruded outward from the sidewall(s) of the semiconductor package element 100. In some embodiments, the wall structure 16 and the lid 20 include the same highly thermally conductive material such as a metal material (i.e. copper or aluminum).

In accordance with the embodiments of the present disclosure, the heat transfer enhancing layer(s) is formed on the element(s) with higher heat dissipation needs, and thermal interface material layer(s) or adhesive material layer(s) is formed on the element(s) with lower heat dissipation needs. By forming thermally conductive layers using materials of different thermal conductivity, the requirement of improving heat-dissipation and reducing delamination can be balanced. As such, production yield and reliability of the semiconductor packages are improved.

In accordance with some embodiments of the disclosure, a semiconductor package is described. The package includes a substrate, a first semiconductor element, a second semiconductor element, and a third semiconductor element. The first semiconductor element is disposed on and electrically connected to the substrate. The second semiconductor element is disposed on and electrically connected to the substrate and disposed beside the first semiconductor element. The third semiconductor element is disposed on and electrically connected to the substrate and disposed beside the first and second semiconductor elements. A heat transfer enhancing layer is disposed on and joined to the first semiconductor element. A thermal conductive material layer is disposed on and joined to the second semiconductor element. An adhesive material layer is disposed on and joined to the third semiconductor element. A lid is disposed over the first, second and third semiconductor elements, and joined to the heat transfer enhancing layer, the thermal conductive material layer and the adhesive material layer. The thermal conductive material layer has a thermal conductivity lower than that of the heat transfer enhancing layer and higher than that of the adhesive material layer, and the thermal conductive material layer has a bonding strength larger than that of the heat transfer enhancing layer and smaller than that of the adhesive material layer.

In accordance with some embodiments of the disclosure, a semiconductor package includes a substrate, a first semiconductor element, a second semiconductor element, a third semiconductor element, and a wall structure disposed on the substrate. The first semiconductor element is disposed on and electrically connected to the substrate, and located within the wall structure. The second semiconductor element is disposed on and electrically connected to the substrate, disposed beside the first semiconductor element, and located within the wall structure. The third semiconductor element is disposed on and electrically connected to the substrate, disposed beside the first and second semiconductor elements, and located within the wall structure. A heat transfer enhancing layer is disposed on and joined to the first semiconductor element. A thermal conductive material layer is disposed on and joined to the second semiconductor element. An adhesive material layer is disposed on and joined to the third semiconductor element. A lid is disposed over the first, second and third semiconductor elements and over the wall structure. The lid is joined to the wall structure, the heat transfer enhancing layer, the thermal conductive material layer and the adhesive material layer. The thermal conductive material layer has a thermal conductivity lower than that of the heat transfer enhancing layer and higher than that of the adhesive material layer, and the thermal conductive material layer has a bonding strength larger than that of the heat transfer enhancing layer and smaller than that of the adhesive material layer. The heat transfer enhancing layer has a stiffness larger than that of the thermal conductive material layer and that of the adhesive material layer.

In accordance with some embodiments of the disclosure, a manufacturing method of a semiconductor package includes the following steps. A substrate is provided. A first semiconductor element is disposed on and bonded to the substrate, wherein the first semiconductor element is electrically connected to the substrate. A second semiconductor element and a third semiconductor element are disposed on and bonded to the substrate. The second semiconductor element and the third semiconductor element are electrically connected to the substrate and are disposed beside the first semiconductor element. A heat transfer enhancing layer is formed on the first semiconductor element by lamination. A thermal conductive material layer is formed on the second semiconductor element by dispensing. An adhesive material layer is formed on the third semiconductor element by dispensing. The thermal conductive material layer has a thermal conductivity lower than that of the heat transfer enhancing layer and higher than that of the adhesive material layer, and the thermal conductive material layer has a bonding strength larger than that of the heat transfer enhancing layer and smaller than that of the adhesive material layer. A lid is attached to the heat transfer enhancing layer, the thermal conductive material layer and the adhesive material layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package, comprising:
a substrate;
a first semiconductor element, disposed on and electrically connected to the substrate;
a second semiconductor element, disposed on and electrically connected to the substrate and disposed beside the first semiconductor element;
a third semiconductor element, disposed on and electrically connected to the substrate and disposed beside the first and second semiconductor elements;
a heat transfer enhancing layer disposed on and joined to the first semiconductor element;
a thermal conductive material layer disposed on and joined to the second semiconductor element;
an adhesive material layer disposed on and joined to the third semiconductor element; and
a lid, disposed over the first, second and third semiconductor elements, and joined to the heat transfer enhancing layer, the thermal conductive material layer and the adhesive material layer,
wherein the thermal conductive material layer has a thermal conductivity lower than that of the heat transfer enhancing layer and higher than that of the adhesive material layer, and the thermal conductive material layer has a bonding strength larger than that of the heat transfer enhancing layer and smaller than that of the adhesive material layer.

2. The package of claim 1, wherein the heat transfer enhancing layer includes a film-type thermal interface material, and the thermal conductive material layer includes a gel-type thermal interface material.

3. The package of claim 2, wherein the heat transfer enhancing layer has a stiffness larger than that of the thermal conductive material layer.

4. The package of claim 1, further comprising a wall structure disposed on the substrate and located between the substrate and the lid.

5. The package of claim 4, wherein the wall structure includes a ring wall and ribs connected to the ring wall to divide a space enclosed by the ring wall.

6. The package of claim 4, wherein the lid includes a first portion joined with the heat transfer enhancing layer, a second portion joined with the thermal conductive material layer and the adhesive material layer, the first portion has a first thickness larger than a second thickness of the second portion.

7. The package of claim 6, wherein the lid further includes a third portion connecting the first and second portions, and the third portion is connected with the wall structure.

8. The package of claim 7, further comprising a first adhesive located between the wall structure and the substrate, and a second adhesive located between the third portion and the wall structure.

9. A package, comprising:
a substrate;
a wall structure located on the substrate;
a first semiconductor element, disposed on and electrically connected to the substrate, and located within the wall structure;
a second semiconductor element, disposed on and electrically connected to the substrate, disposed beside the first semiconductor element, and located within the wall structure;
a third semiconductor element, disposed on and electrically connected to the substrate, disposed beside the first and second semiconductor elements, and located within the wall structure;
a heat transfer enhancing layer disposed on and joined to the first semiconductor element;
a thermal conductive material layer disposed on and joined to the second semiconductor element;
an adhesive material layer disposed on and joined to the third semiconductor element; and
a lid, disposed over the first, second and third semiconductor elements and over the wall structure, and joined to the wall structure, the heat transfer enhancing layer, the thermal conductive material layer and the adhesive material layer,
wherein the thermal conductive material layer has a thermal conductivity lower than that of the heat transfer enhancing layer and higher than that of the adhesive material layer, and the thermal conductive material layer has a bonding strength larger than that of the heat transfer enhancing layer and smaller than that of the adhesive material layer, and the heat transfer enhancing layer has a stiffness larger than that of the thermal conductive material layer and that of the adhesive material layer.

10. The package of claim 9, wherein the first semiconductor element includes a first die having an active surface and a backside surface opposite to the active surface, and a first encapsulant laterally wrapping the first die, the heat transfer enhancing layer contacts the backside surface of the first die and the first encapsulant.

11. The package of claim 10, wherein the heat transfer enhancing layer has a span larger than that of the first encapsulant, and the heat transfer enhancing layer has an extended portion protruded out and spaced apart from a sidewall of the first encapsulant.

12. The package of claim 9, wherein the heat transfer enhancing layer has a vertical projection fully overlaps with a vertical projection of the first semiconductor element.

13. The package of claim 9, wherein the heat transfer enhancing layer has a vertical projection partially overlaps with a vertical projection of the first semiconductor element.

14. The package of claim 9, wherein the adhesive material layer disposed on the third semiconductor element is located near a corner of the package.

15. The package of claim 9, wherein the lid includes a first portion joined with the heat transfer enhancing layer, a second portion joined with the thermal conductive material layer and the adhesive material layer, and a third portion connecting the first and second portions, wherein the third portion has a thickness smaller that that of the first portion and that of the second portion.

16. The package of claim 15, wherein the third portion is connected with the wall structure through an adhesive located therebetween.

17. A method of manufacturing a package, comprising:
providing a substrate;
disposing and bonding a first semiconductor element onto the substrate, wherein the first semiconductor element is electrically connected to the substrate;
disposing and bonding a second semiconductor element and a third semiconductor element on the substrate, wherein the second semiconductor element and the third semiconductor element are electrically connected to the substrate and are disposed beside the first semiconductor element;
laminating a heat transfer enhancing layer on the first semiconductor element;
dispensing a thermal conductive material layer on the second semiconductor element;
dispensing an adhesive material layer on the third semiconductor element, wherein the thermal conductive material layer has a thermal conductivity lower than that of the heat transfer enhancing layer and higher than that of the adhesive material layer, and the thermal conductive material layer has a bonding strength larger than that of the heat transfer enhancing layer and smaller than that of the adhesive material layer; and
attaching a lid to the heat transfer enhancing layer, the thermal conductive material layer and the adhesive material layer.

18. The manufacturing method of claim 17, wherein laminating a heat transfer enhancing layer on the first semiconductor element includes laminating a film-type thermal interface material on the first semiconductor element.

19. The manufacturing method of claim 17, wherein dispensing a thermal conductive material layer on the second semiconductor element includes dispensing a gel-type thermal interface material on the second semiconductor element.

20. The manufacturing method of claim 17, further comprising disposing a wall structure on the substrate and between the lid and the substrate before attaching the lid.
